(19) United States
(12) Patent Application Publication
(10) Pub. No.: US 2012/0292648 A1
(43) Pub. Date: Nov. 22, 2012

(54) NITRIDE SEMICONDUCTOR DEVICE, NITRIDE SEMICONDUCTOR WAFER, AND METHOD FOR MANUFACTURING NITRIDE SEMICONDUCTOR LAYER

(75) Inventors: Hiroshi Ono, Kanagawa-ken (JP); Tomonari Shioda, Kanagawa-ken (JP); Naoharu Sugiyama, Kanagawa-ken (JP); Toshiyuki Oka, Kanagawa-ken (JP); Shinya Nunoue, Chiba-ken (JP)

(73) Assignee: Kabushiki Kaisha Toshiba, Tokyo (JP)

(21) Appl. No.: 13/219,011

(22) Filed: Aug. 26, 2011

(30) Foreign Application Priority Data
May 16, 2011 (JP) 2011-109191

(51) Int. Cl. H01L 33/30; H01L 21/20

(52) U.S. Cl. 257/94; 438/478; 257/E33.023; 257/E21.09

(57) ABSTRACT

According to one embodiment, a nitride semiconductor device includes a foundation layer and the functional layer. The foundation layer is formed on an amorphous layer and includes aluminum nitride. The functional layer is formed on the foundation layer and includes a nitride semiconductor.

### CROSS-REFERENCE TO RELATED APPLICATIONS

This application is based upon and claims the benefit of priority from the prior Japanese Patent Application No. 2011-109191, filed on May 16, 2011; the entire contents of which are incorporated herein by reference.

### FIELD

Embodiments described herein relate generally to a nitride semiconductor device, a nitride semiconductor wafer, and a method for manufacturing a nitride semiconductor layer.

### BACKGROUND

Various kinds of nitride semiconductor devices using a nitride semiconductor, such as gallium nitride, have been developed. Examples thereof include semiconductor light emitting devices, such as an ultraviolet, blue, or green light emitting diode (LED), and a purple-blue or blue laser diode (LD).

A GaN layer of the nitride semiconductor device is usually formed on a sapphire substrate or the like. However, due to a reduction in cost and an increase in diameter of a wafer, it is desirable to establish a technique for growing the GaN layer on a substrate other than the sapphire substrate.

### BRIEF DESCRIPTION OF THE DRAWINGS

FIG. 1 is a schematic cross-sectional view showing a nitride semiconductor device according to a first embodiment;

FIG. 2 is a schematic cross-sectional view showing the nitride semiconductor device according to the first embodiment;

FIG. 3 is a schematic cross-sectional view showing a part of the nitride semiconductor device according to the first embodiment;

FIG. 4 is an RHEED image showing characteristics of an AlN layer fabricated in the experiment;

FIG. 5 is a graph showing characteristics of the AlN layer fabricated in the experiment;

FIG. 6 is a schematic cross-sectional view showing another nitride semiconductor device according to the first embodiment;

FIG. 7 is a schematic cross-sectional view showing another nitride semiconductor device according to the first embodiment;

FIG. 8 is a schematic cross-sectional view showing another nitride semiconductor device according to the first embodiment;

FIG. 9 is a schematic cross-sectional view showing yet another nitride semiconductor device according to the first embodiment;

FIG. 10 is graph showing an XRD analysis result showing the characteristics of an Al film fabricated in the experiment;

FIGS. 11A and 11B are schematic cross-sectional views each showing a nitride semiconductor wafer according to a second embodiment.

FIGS. 12A and 12B are flowcharts each showing a method for manufacturing a nitride semiconductor layer according to a third embodiment.

### DETAILED DESCRIPTION

In general, according to one embodiment, a nitride semiconductor device includes a foundation layer and a functional layer. The foundation layer is formed on an amorphous layer and includes aluminum nitride. The functional layer is formed on the foundation layer and includes a nitride semiconductor.

According to another embodiment, a nitride semiconductor wafer includes a substrate, an amorphous layer, a foundation layer, and a functional layer. The amorphous layer is provided on the substrate. The foundation layer is provided on the amorphous layer and includes aluminum nitride. The functional layer is formed on the foundation layer and includes a nitride semiconductor.

According to another embodiment, a method for manufacturing a nitride semiconductor layer is disclosed. The method can form an amorphous layer on a substrate. The method can form a foundation layer including aluminum nitride on the amorphous layer. In addition, the method can form a functional layer including a nitride semiconductor on the foundation layer.

Exemplary embodiments of the invention will now be described in detail with reference to the drawings.

The drawings are schematic or conceptual; and the relationships between the thickness and width of portions, the proportions of sizes among portions, etc., are not necessarily the same as the actual values thereof. Further, the dimensions and proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

The embodiment relates to nitride semiconductor devices. A nitride semiconductor device according to the embodiment includes semiconductor devices, such as a semiconductor light emitting device, a semiconductor light receiving device, and an electron device. The examples of the semiconductor light emitting device include a light emitting diode (LED), a laser diode (LD), and the like. The semiconductor light receiving device includes a photodiode (PD) and the like. The examples of the electron device include a high electron mobility transistor (HEMT), a hetero junction bipolar transistor (HBT), a field effect transistor (FET), a schottky barrier diode (SBD), and the like.

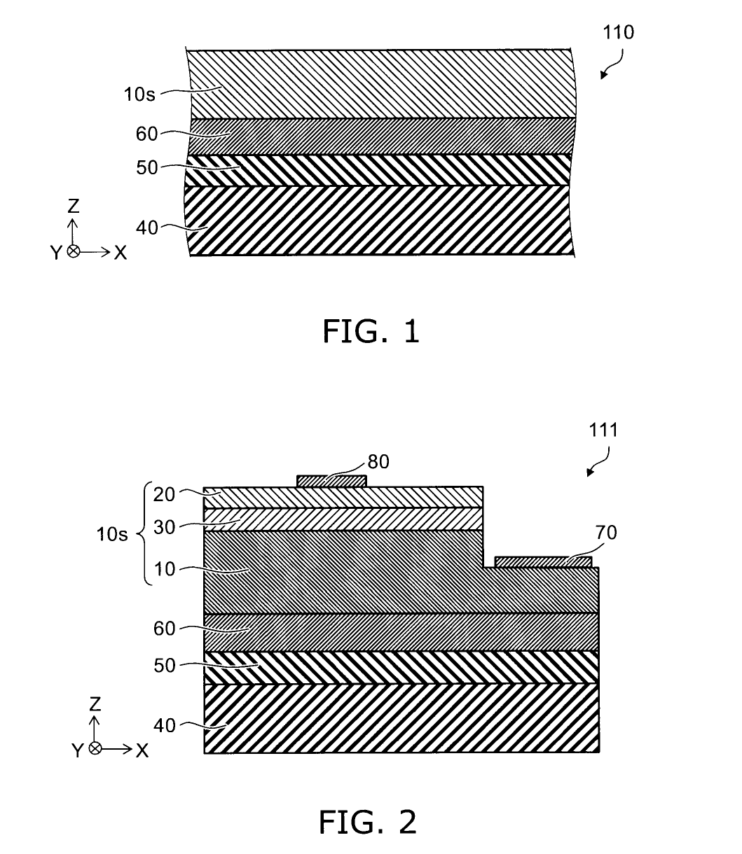

FIG. 1 is a schematic cross-sectional view illustrating the configuration of a nitride semiconductor device according to a first embodiment.

As shown in FIG. 1, a nitride semiconductor device 110 according to the embodiment includes a foundation layer 60 and a functional layer 10s. The foundation layer 60 is formed on an amorphous layer 50. The foundation layer 60 includes aluminum nitride (AlN). The amorphous layer 50 is provided on a substrate 40, for example. The functional layer 10s includes a nitride semiconductor.

The direction from the foundation layer 60 toward the functional layer 10s is defined as a Z-axis direction. One axis perpendicular to the Z-axis is defined as an X-axis. The direction perpendicular to the Z-axis and the X-axis is defined as a Y-axis.

Hereinafter, a case is described where the nitride semiconductor device 110 is a light emitting device.

FIG. 2 is a schematic cross-sectional view illustrating the configuration of the nitride semiconductor device according to the first embodiment.

As shown in FIG. 2, in a nitride semiconductor device 111 which is one example according to the embodiment, the functional layer 10s includes a first semiconductor layer 10, a light emitting part 30, and a second semiconductor layer 20. The first semiconductor layer 10 is formed on the foundation layer 60. The first semiconductor layer 10 includes a nitride semiconductor and is of a first conductivity type. The light emitting part 30 is provided on the first semiconductor layer 10. The second semiconductor layer 20 is provided on the light emitting part 30. The second semiconductor layer 20 includes a nitride semiconductor and is of a second conductivity type. The second conductivity type differs from the first conductivity type.

For example, the first conductivity type is an n-type and the second conductivity type is a p-type. Moreover, the first conductivity type may be a p-type and the second conductivity type may be an n-type. Hereinafter, the description is made on the case where the first conductivity type is an n-type and the second conductivity type is a p-type.

The nitride semiconductor device 110 can further include a first electrode 70 and a second electrode 80. The first electrode 70 is electrically connected to the first semiconductor layer 10. The second electrode 80 is electrically connected to the second semiconductor layer 20.

In this example, in the major surface on a side of the second semiconductor layer 20 of the functional layer 10s, a part of the first semiconductor layer 10 and the second semiconductor layer 20 are exposed. On the major surface side, the first electrode 70 and the second electrode 80 are connected to the first semiconductor layer 10 and the second semiconductor layer 20, respectively.

By applying a voltage between the first electrode 70 and the second electrode 80, a current is supplied to the light emitting part 30 via the first semiconductor layer 10 and the second semiconductor layer 20 and light is emitted from the light emitting part 30.

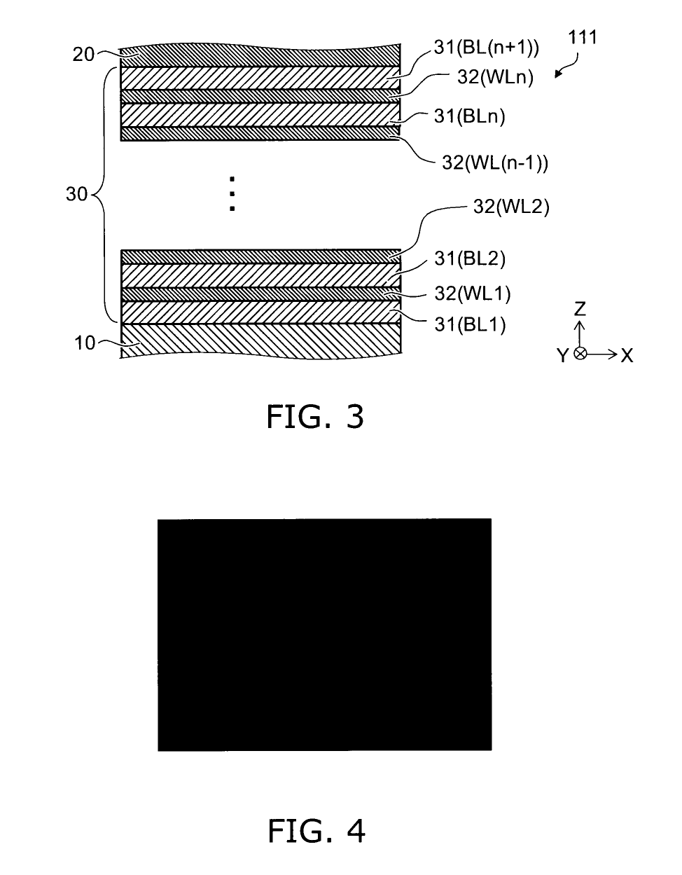

FIG. 3 is a schematic cross-sectional view illustrating the configuration of a part of the nitride semiconductor device according to the first embodiment.

As shown in FIG. 3, the light emitting part 30 includes a plurality of barrier layers 31 and the well layers 32 provided between the barrier layers 31. For example, the barrier layers 31 and the well layers 32 are alternately stacked along the Z-axis.

In the specification, a “stacked layer” includes the case where layers are stacked while another layer is inserted therebetween other than the case where layers are stacked in contact with each other. Moreover, “being provided on” includes the case of being provided while another layer is inserted therebetween other than the case of being provided directly in contact therewith.

The well layer 32 includes Inₓ₁Ga₁₋ₓ₁N (0<x1<1), for example. The barrier layer 31 includes GaN, for example. That is, the barrier layer 31 contains In and the well layer 32 does not substantially contain In, for example. The bandgap energy in the barrier layer 31 is larger than the bandgap energy in the well layer 32.

The light emitting part 30 may have a single quantum well (SQW) structure. In this case, the light emitting part 30 includes two barrier layers 31 and the well layer 32 provided between the barrier layers 31. Alternatively, the light emitting part 30 may have a multi quantum well (MQW) structure. In this case, the light emitting part 30 includes three or more barrier layers 31 and the well layer 32 provided between the respective barrier layers 31.

That is, the light emitting part 30 includes (n+1) barrier layers 31 and n well layers 32 (“n” is an integer not less than 2). The (i+1)th barrier layer BL(i+1) is arranged between the i-th barrier layer BLi and the second semiconductor layer 20 (“i” is an integer not less than 1 and not more than (n−1)). The (i+1)th well layer WL(i+1) is arranged between the i-th well layer WLi and the second semiconductor layer 20. The first barrier layer BL1 is provided between the first semiconductor layer 10 and the first well layer WL1. The n-th well layer WLn is provided between the n-th barrier layer BLn and the (n+1)th barrier layer BL(n+1). The (n+1)th barrier layer BL(n+1) is provided between the n-th well layer WLn and the second semiconductor layer 20.

The peak wavelength of light (luminescent light) emitted from the light emitting part 30 is not less than 400 nanometers (nm) and not more than 650 nm, for example. However, in the embodiment, the peak wavelength is arbitrary.

For the first semiconductor layer 10, a GaN layer containing an n-type impurity is used, for example. For the n-type impurity, at least one of Si, Ge, Te and Sn can be used. The first semiconductor layer 10 includes an n-side contact layer, for example.

For the second semiconductor layer 20, a GaN layer containing a p-type impurity is used, for example. For the p-type impurity, at least one of Mg, Zn, and C can be used. The second semiconductor layer 20 includes a p-side contact layer, for example.

As illustrated in FIG. 1 and FIG. 2, the nitride semiconductor devices 110 and 111 according to the embodiment can further include the substrate 40. The substrate 40 is provided as required and may be omitted.

For the substrate 40, Si is used, for example. The embodiment is not limited thereto, and for example, for the substrate 40, one of Si, SiO₂, quartz, sapphire, GaN, SiC and GaAs is used. Then, the plane direction of the substrate 40 is arbitrary. In the following, an example using a Si substrate as the substrate 40 is described.

On the substrate 40, the amorphous layer 50 is formed. On the amorphous layer 50, the foundation layer 60 of AlN is formed. Then, preferably, the foundation layer 60 is orientated substantially in the Z-axis direction (the direction perpendicular to the layer face of the foundation layer 60).

On the foundation layer 60, the first semiconductor layer 10 is formed. On the first semiconductor layer 10, the light emitting part 30 is formed. On the light emitting part 30, the second semiconductor layer 20 is formed. For example, the substrate 40 may be removed after forming the functional layer 10s (the first semiconductor layer 10, the light emitting part 30, and the second semiconductor layer 20).

For the amorphous layer 50, SiO₂ is used, for example. The embodiment is not limited thereto, and for the amorphous layer 50, one of SiO₂ and the amorphous Si is used, for example. Moreover, for the amorphous layer 50, an amorphous metal film (TaAl or the like) may be used. SiO₂ or amorphous Si is used as the amorphous layer 50, and thus the thermal stability of the amorphous layer 50 increases. Therefore, the process resistance during the formation of the functional layer 10s formed thereon will improve, which is more preferable.

In this manner, in the nitride semiconductor devices 110 and 111 according to the embodiment, an AlN layer (foundation layer 60) is provided on the amorphous layer 50. Therefore, on the substrate 40 having a crystallinity different from the functional layer 10s (e.g., GaN layer), the functional layer 10s with a high crystal quality can be formed.

Hereinafter, the experimental result forming the basis for building the configuration according to the embodiment is described.

The inventors formed various amorphous layers on a Si (100) substrate, and formed an AlN layer on the amorphous layers.

A TaAl film, SiO₂ film, or a-Si film was formed as the amorphous layer.

FIG. 4 is an RHEED image illustrating characteristics of an AlN layer fabricated in the experiment.

This figure shows the RHEED image of a sample, wherein a TaAl film is formed as an amorphous layer and the AlN layer is formed thereon.

As shown in FIG. 4, in the RHEED image, spot (dot) bright points can be observed. This indicates that the plane directions of the AlN layer are aligned.

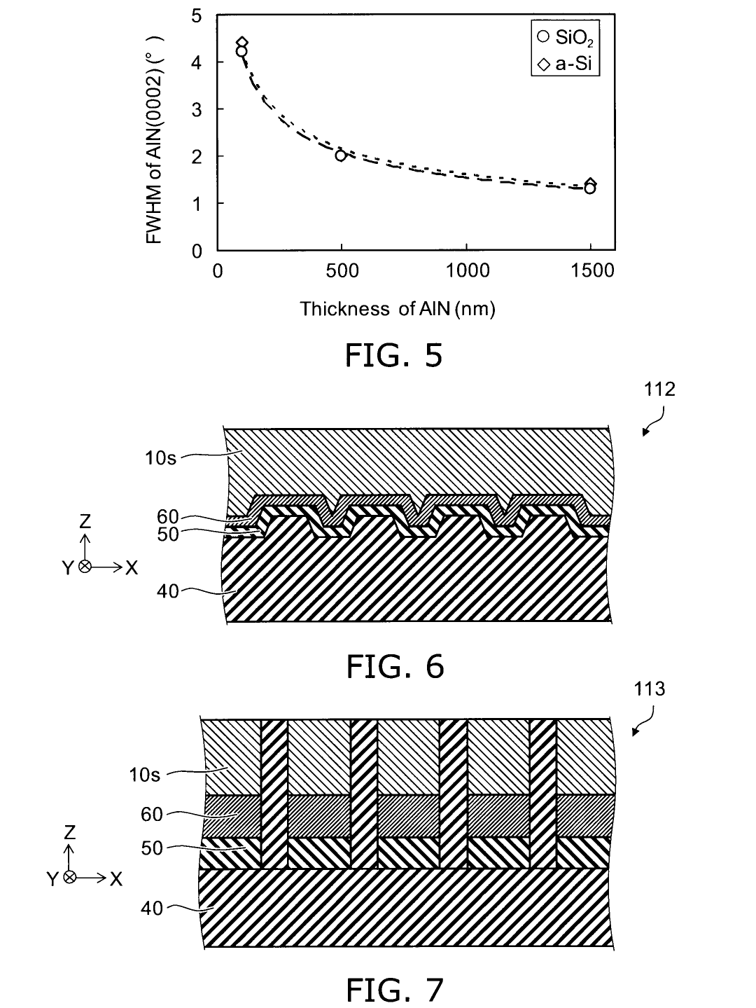

FIG. 5 is a graph illustrating characteristics of the AlN layer fabricated in the experiment.

This graph shows the measurement results of an XRD full width at half maximum of a sample, wherein a SiO₂ film or a-Si film is formed as the amorphous layer and an AlN layer is formed thereon. The horizontal axis represents the thickness of the AlN layer, while the vertical axis represents the XRD full width at half maximum.

As shown in FIG. 5, in either case of the SiO₂ film or a-Si film, a high orientation can be obtained in the AlN layer.

As described above, it was found that by forming an AlN layer (foundation layer 60) on the amorphous layer 50, it is possible to from an AlN layer (foundation layer 60) exhibiting a high orientation even on the substrate 40 (Si substrate, in this example) having a crystallinity different from the AlN layer.

The crystal quality of the functional layer 10s can be improved by growing the functional layer 10s on such a foundation layer 60.

In the embodiment, the foundation layer 60 preferably has a residual strain adequate to the crystal growth of the functional layer 10s. For example, the foundation layer 60 can apply a compression stress to the functional layer 10s. Alternatively, the foundation layer 60 can apply a tensile stress to the functional layer 10s. Therefore, in the functional layer 10s, excellent characteristics (e.g., the controllability of injection of charges, the suppression of a crack, a reduction in dislocation density, and the like) can be obtained.

FIG. 6 is a schematic cross-sectional view illustrating the configuration of another nitride semiconductor device according to the first embodiment.

As shown in FIG. 6, in another nitride semiconductor device 112 according to the embodiment, the amorphous layer 50 has recesses and projections. For example, the recesses and projections are formed in the amorphous layer 50 by forming recesses and projections on the major surface of the substrate 40. Also in such a nitride semiconductor device 112, the foundation layer 60 having an excellent and uniform crystallinity in the plane can be obtained by forming the foundation layer 60 of AlN on the amorphous layer 50. Therefore, the functional layer 10s having an excellent characteristic can be obtained.

Furthermore, an inclined face may be provided in the recesses and projections of the amorphous layer 50. For example, an inclined face is formed in the recesses and projections of the amorphous layer 50 by providing an inclined face in the recesses and projections formed in the substrate 40.

FIG. 7 is a schematic cross-sectional view illustrating the configuration of another nitride semiconductor device according to the first embodiment.

As shown in FIG. 7, in another nitride semiconductor device 113 according to the embodiment, the amorphous layer 50 provided on the substrate 40 is patterned and partially provided. Moreover, in this example, the foundation layer 60 is partially provided. Furthermore, the functional layer 10s is partially provided. In this manner, at least one of the amorphous layer 50, the foundation layer 60, and the functional layer 10s can be provided in a plurality of regions in the X-Y plane. Between a region with these layers and a region without them, the crystallinity of a layer formed on the respective regions is varied, and thus selective concentration of defects can be achieved. Therefore, an excellent crystal having a small number of defects in a necessary region can be obtained.

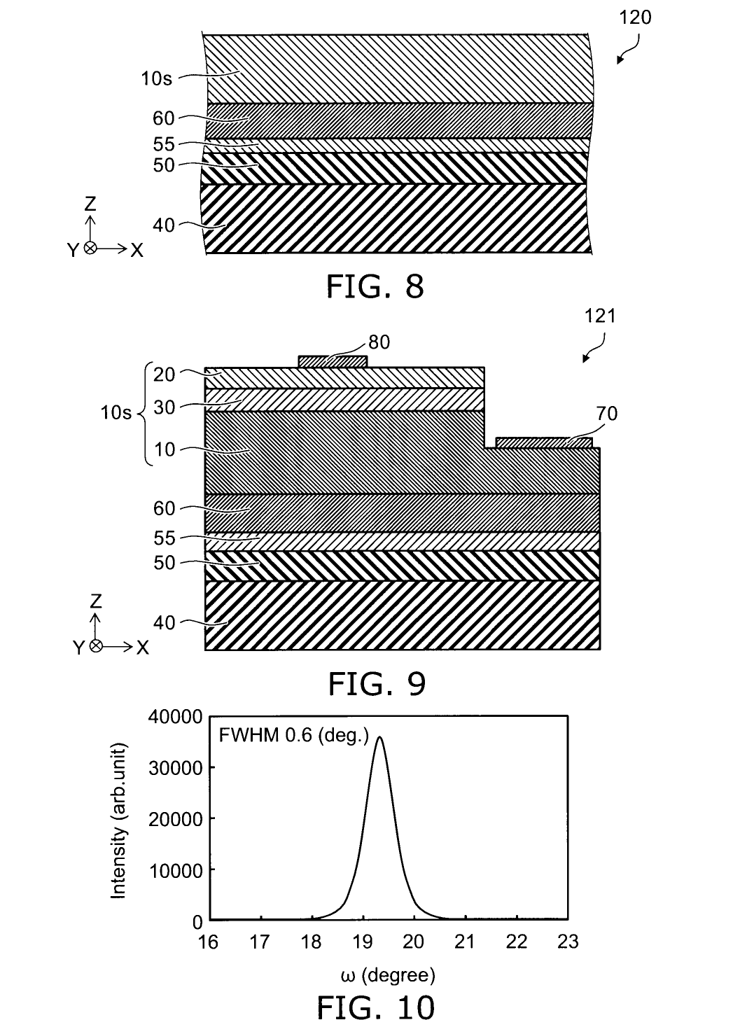

FIG. 8 is a schematic cross-sectional view illustrating the configuration of another nitride semiconductor device according to the first embodiment.

FIG. 9 is a schematic cross-sectional view illustrating the configuration of yet another nitride semiconductor device according to the first embodiment.

As shown in FIG. 8 and FIG. 9, in another nitride semiconductor device 120 and another nitride semiconductor device 121 according to the embodiment, the foundation layer 60 is provided on an orientation layer 55 provided on the amorphous layer 50. Other than this is the same as in the case of the nitride semiconductor devices 110 and 111, and thus the description thereof is omitted. Hereinafter, the orientation layer 55 is described. For the orientation layer 55, Al is used, for example.

The inventors formed a TaAl film as the amorphous layer 50 on a Si (100) substrate, and formed, on the TaAl film, an Al film to serve as the orientation layer 55.

FIG. 10 is graph showing an XRD analysis result illustrating the characteristics of an Al film fabricated in the experiment.

The horizontal axis of FIG. 10 represents an angle ω while the vertical axis represents the intensity of XRD.

As shown in FIG. 10, it was found that the orientation layer 55 (Al film) formed on the amorphous layer 50 (TaAl film) exhibits high orientation. In this example, the XRD full width at half maximum of the orientation layer 55 (Al film) is 0.6 degrees. In this manner, the foundation layer 60 of high orientation can be obtained by forming the foundation layer 60 (AlN layer) on the orientation layer 55 of high orientation. Then, the functional layer 10s of high orientation can be obtained.

In the embodiment, for the orientation layer 55, at least one of Al, Cu, Au, Ag, Ir, Ni, Pt, Mo, and W is used, for example.

The orientation layer 55 preferably has one of a face-centered cubic lattice structure and a body-centered cubic lattice structure. The XRD full width at half maximum of the orientation layer 55 is preferably not more than 10 degrees.

In this manner, in the nitride semiconductor devices 120 and 121 according to the embodiment, the orientation layer 55 is formed on the amorphous layer 50 and the foundation layer (AlN layer) is provided on the orientation layer 55. Introduction of the orientation layer 55 can further improve the orientation of the foundation layer 60. Moreover, the introduction of the orientation layer 55 enables to achieve a reduction in thickness of the foundation layer 60. Therefore, a nitride semiconductor layer of high crystal quality can be formed even on the substrate 40 having a different crystallinity. Therefore, a nitride semiconductor device which can be formed on any substrate and has excellent crystallinity can be obtained.

There is a method of introducing a buffer layer for relaxing lattice mismatch as a method for growing GaN on a substrate other than the sapphire substrate. For example, there is a method for forming a Zr (zirconium) film on a silicon substrate and growing a GaN layer thereon and thereby relaxing the lattice mismatch between the silicon substrate and the GaN layer. However, in this method, the buffer layer is introduced for the purpose of relaxing the lattice mismatch between the substrate and GaN, and therefore there is a limitation for the substrate to be used.

In contrast, in the embodiment, by introducing the amorphous layer 50 for canceling the crystallinity of the substrate, a nitride semiconductor layer having high crystal quality can be formed even on the substrate 40 having a different crystallinity.

### Second Embodiment

This embodiment relates to a nitride semiconductor wafer. In this wafer, there is provided at least a part of a semiconductor device or a portion serving as a part of the semiconductor device, for example. This semiconductor device includes a semiconductor light emitting device, a semiconductor light receiving device, an electron device, and the like, for example.

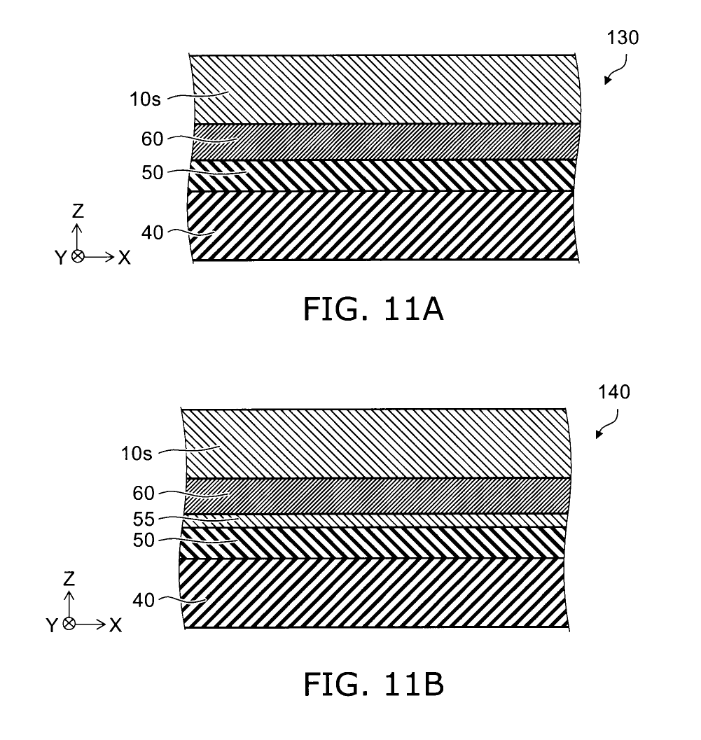

FIGS. 11A and 11B are schematic cross-sectional views each illustrating the configuration of a nitride semiconductor wafer according to a second embodiment.

As shown in FIG. 11A, a nitride semiconductor wafer 130 according to the embodiment includes: the substrate 40; the amorphous layer 50 provided on the substrate 40; the foundation layer 60 provided on the amorphous layer 50, the foundation layer 60 including aluminum nitride; and the functional layer 10s formed on the foundation layer 60, the functional layer 10s including a nitride semiconductor.

To the substrate 40, amorphous layer 50, foundation layer 60, and functional layer 10s, the configuration described with regard to the first embodiment can be applied.

For example, the amorphous layer 50 is a layer of one of silicon oxide and amorphous silicon. Moreover, the amorphous layer 50 may be a layer of an amorphous metal. The foundation layer 60 is preferably oriented in a direction perpendicular to the layer face of the foundation layer 60.

As with the nitride semiconductor device 110 illustrated in FIG. 1, the functional layer 10s can include the first semiconductor layer 10, the light emitting part 30, and the second semiconductor layer 20. The first semiconductor layer 10 is formed on the foundation layer 60, includes a nitride semiconductor, and is of a first conductivity type. The light emitting part 30 is provided on the first semiconductor layer 10, and includes a plurality of barrier layers 31 and a well layer 32 provided between the barrier layers 31. The second semiconductor layer 20 is provided on the light emitting part 30, includes a nitride semiconductor, and is of a second conductivity type different from the first conductivity type.

As shown in FIG. 11B, another nitride semiconductor wafer 140 according to the embodiment further includes the orientation layer 55 provided between the amorphous layer 50 and the foundation layer 60. To the orientation layer 55, the configuration described with regard to the first embodiment can be applied.

For example, the orientation layer 55 preferably has one of a face-centered cubic lattice structure and a body-centered cubic lattice structure. The substrate 40 is preferably a silicon substrate.

### Third Embodiment

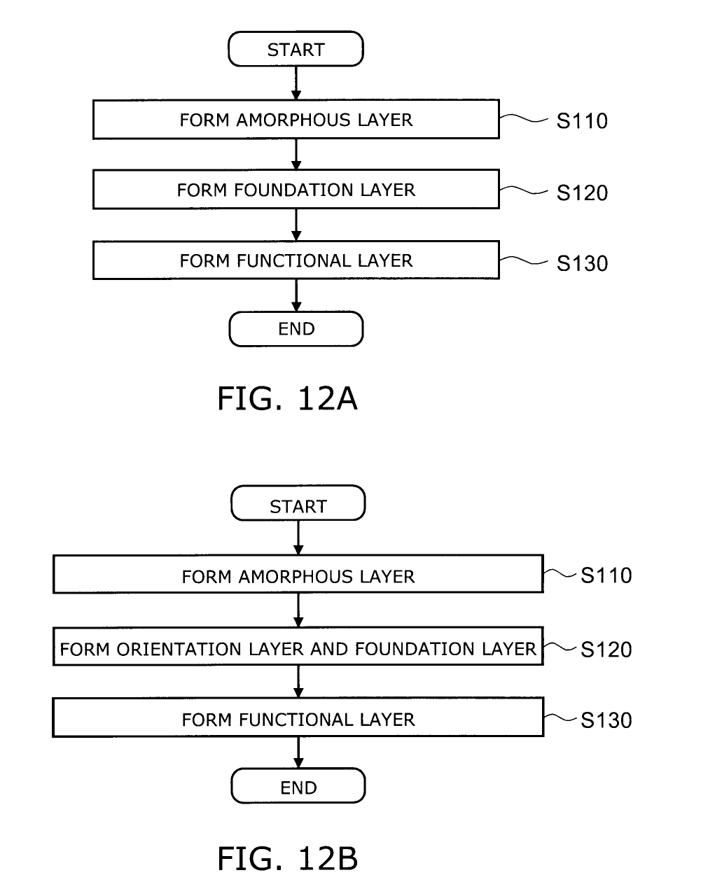

FIGS. 12A and 12B are flowcharts each illustrating a method for manufacturing nitride semiconductor layers according to a third embodiment.

As shown in FIG. 12A, in this manufacturing method, the amorphous layer 50 is formed on the substrate 40 (Step S110). Then, the foundation layer 60 including aluminum nitride is formed on the amorphous layer 50 (Step S120). Then, the functional layer 10s including a nitride semiconductor is formed on the foundation layer 60 (Step S130).

As shown in FIG. 12B, in this manufacturing method, forming the foundation layer 60 (Step S120) includes forming the orientation layer 55 on the amorphous layer 50 and forming the foundation layer 60 on the orientation layer 55.

The orientation layer 55 may have one of a face-centered cubic lattice structure and a body-centered cubic lattice structure, for example.

A sputtering method is used in the forming at least one of the amorphous layer 50 and the foundation layer 60, for example. Use of the sputtering method allows the control of the orientation of a film. Furthermore, a residual strain can be controlled in a wide range. This provides an advantage in improving the crystallinity of the functional layer 10s.

In the forming at least one of the amorphous layer 50 and the foundation layer 60, CVD may be used, for example. When CVD is used, these layers and the functional layer 10s can be continuously formed.

When a Si substrate is used as the substrate 40 and a SiO₂ layer is used as the amorphous layer 50, the amorphous layer 50 may be formed by thermal oxidation.

In this manufacturing method, the amorphous layer 50 includes one of silicon oxide and amorphous silicon, for example. Moreover, the amorphous layer 50 may be a layer of an amorphous metal. Moreover, the foundation layer 60 is orientated in the direction perpendicular to the layer face of the foundation layer 60, for example.

In the formation of the functional layer 10s, for example, the first semiconductor layer 10 is formed on the foundation layer 60, the light emitting part 30 is formed thereon, and the second semiconductor layer 20 is formed thereon. Then, the first electrode 70 and the second electrode 80 are formed, and thus the nitride semiconductor device according to the embodiment is fabricated. The substrate 40 may be removed in any technically feasible process.

In the method for manufacturing the nitride semiconductor device, nitride semiconductor wafer, and nitride semiconductor layer according to the embodiment, for example, metal-organic chemical vapor deposition (MOCVD), metal-organic vapor phase epitaxy, or the like can be used as the method for growing semiconductor layers.

In the manufacturing method according to the embodiment, a nitride semiconductor layer having excellent crystallinity can be manufactured on any substrate.

According to the embodiment, a nitride semiconductor device which can be formed on any substrate and has excellent crystallinity, a nitride semiconductor wafer, and a method for manufacturing nitride semiconductor layers can be provided.

In the specification, “nitride semiconductor” includes all compositions of semiconductors of the chemical formula BₓIn_{y}Al_{z}Ga_{1-x-y}N (0≦x≦1, 0≦y≦1, 0≦z≦1, and x+y+z≦1) for which each of the compositional proportions x, y, and z are changed within the ranges. “Nitride semiconductor” further includes group V elements other than N (nitrogen) in the chemical formula recited above, various elements added to control various properties such as the conductivity type, etc., and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific structures of components, such as a substrate, an amorphous layer, a foundation layer, an orientation layer, a semiconductor layer, a light emitting part, and an electrode, included in a nitride semiconductor device and wafer, from known art.

Further, any two or more components of the specific examples may be combined within the extent of technical feasibility and are included in the scope of the embodiments to the extent that the spirit of the embodiments is included.

Moreover, all the nitride semiconductor devices, nitride semiconductor wafers, and methods for manufacturing nitride semiconductor layers practicable by an appropriate design modification by one skilled in the art based on the nitride semiconductor devices, nitride semiconductor wafers, and methods for manufacturing nitride semiconductor layers described above as embodiments of the invention also are within the scope of the invention to the extent that the purport of the embodiments of the invention is included.

Furthermore, various modifications and alterations within the spirit of the invention will be readily apparent to those skilled in the art.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride semiconductor device, comprising:
a foundation layer formed on an amorphous layer and including aluminum nitride; and
a functional layer formed on the foundation layer and including a nitride semiconductor.

2. The device according to claim 1, wherein the functional layer includes:
a first semiconductor layer of a first conductivity type formed on the foundation layer and including a nitride semiconductor;
a light emitting part provided on the first semiconductor layer and including a plurality of barrier layers and a well layer provided between the barrier layers; and
a second semiconductor layer of a second conductivity type different from the first conductivity type, the second semiconductor layer being provided on the light emitting part and including a nitride semiconductor.

3. The device according to claim 1, wherein the amorphous layer is a layer of one of silicon oxide and amorphous silicon.

4. The device according to claim 1, wherein the amorphous layer is a layer of an amorphous metal.

5. The device according to claim 1, wherein the foundation layer is orientated in a direction perpendicular to a layer face of the foundation layer.

6. The device according to claim 1, wherein the foundation layer is provided on an orientation layer provided on the amorphous layer.

7. The device according to claim 6, wherein the orientation layer has one of a face-centered cubic lattice structure and a body-centered cubic lattice structure.

8. A nitride semiconductor wafer, comprising:
a substrate;
an amorphous layer provided on the substrate;
a foundation layer provided on the amorphous layer and including aluminum nitride; and
a functional layer formed on the foundation layer and including a nitride semiconductor.

9. The wafer according to claim 8, wherein the amorphous layer is a layer of one of silicon oxide and amorphous silicon.

10. The wafer according to claim 8, wherein the foundation layer is orientated in a direction perpendicular to a layer face of the foundation layer.

11. The wafer according to claim 8, further comprising an orientation layer provided between the amorphous layer and the foundation layer.

12. The wafer according to claim 11, wherein the orientation layer has one of a face-centered cubic lattice structure or a body-centered cubic lattice structure.

13. The wafer according to claim 8, wherein the substrate is a silicon substrate.

14. The wafer according to claim 8, wherein the functional layer includes:
a first semiconductor layer of a first conductivity type formed on the foundation layer and including a nitride semiconductor;
a light emitting part provided on the first semiconductor layer and including a plurality of barrier layers and a well layer provided between the barrier layers; and
a second semiconductor layer of a second conductivity type different from the first conductivity type, the second semiconductor layer being provided on the light emitting part and including a nitride semiconductor.

15. A method for manufacturing a nitride semiconductor layer, comprising:
forming an amorphous layer on a substrate;
forming a foundation layer including aluminum nitride on the amorphous layer; and
forming a functional layer including a nitride semiconductor on the foundation layer.

16. The method according to claim 15, wherein the forming the foundation layer includes:
forming an orientation layer on the amorphous layer; and
forming the foundation layer on the orientation layer.

17. The method according to claim 16, wherein the orientation layer has one of a face-centered cubic lattice structure or a body-centered cubic lattice structure.

18. The method according to claim 15, wherein the amorphous layer is a layer of one of silicon oxide and amorphous silicon.

19. The method according to claim 15, wherein the amorphous layer is a layer of an amorphous metal.

20. The method according to claim 15, wherein the foundation layer is orientated in a direction perpendicular to a layer face of the foundation layer.
